(19) United States
(12) Patent Application Publication
(10) Pub. No.: US 2024/0053113 A1
(43) Pub. Date: Feb. 15, 2024

(54) HEAT PIPE HEAT SINK FOR A PULSATING OPERATION, AND METHOD FOR PRODUCING A HEAT PIPE HEAT SINK OF THIS KIND

(71) Applicant: Siemens Aktiengesellschaft, 80333 München (DE)

(72) Inventors: VOLKER MÜLLER, Nürnberg (DE); STEPHAN NEUGEBAUER, Erlangen (DE); FLORIAN SCHWARZ, Fürth, Bayern (DE)

(73) Assignee: Siemens Aktiengesellschaft, 80333 München (DE)

(21) Appl. No.: 18/268,140

(22) PCT Filed: Dec. 1, 2021
(86) PCT No.: PCT/EP2021/083761

§ 371 Date: Jun. 16, 2023

(30) Foreign Application Priority Data
Dec. 17, 2020 (EP) 20215036.3

(51) Int. Cl. F28F 13/10; H05K 7/20

(52) U.S. Cl. CPC F28F 13/10; H05K 7/20936; H05K 7/20336

(57) ABSTRACT

A heat pipe heat sink operating as a pulsating heat pipe includes a body comprising internally a closed channel in which a fluid is arranged such that part of the fluid is present in gaseous form. The channel has a periphery which is designed to be smooth. The body includes a first body portion which is embodied as curved, alternatingly curved, serpentine or U-shaped. A coolant, in particular a gaseous coolant, flows through the first body portion along a surface of the first body portion, wherein portions of the channel are arranged parallel to one another and/or in the presence of more than one channel, different channels are arranged parallel to one another. The body is composed of two block parts, with parts of the channel being arranged on a boundary area of the two block parts, respectively.

The invention relates to a heat pipe heat sink, the heat pipe heat sink being configured for operation as a pulsating heat pipe, the heat pipe heat sink comprising a body. The invention further relates to a method for producing a heat sink of said type. The invention further relates to a power semiconductor unit comprising a heat pipe heat sink of said type and at least one power semiconductor module, as well as to a power converter comprising a heat pipe heat sink of said type or to a power semiconductor unit of said type.

Heat pipe heat sinks have already been established on the market for years as a means of effective cooling. The basic principle is that a fluid vaporizes in a closed pipe of the heat pipe heat sink due to the input of heat from a heat source. As a result of the vacuum in the closed pipe, the fluid condenses at a different point of the pipe, from which the heat can then be dissipated to the ambient air, for example. The capillary effect is used to induce the fluid to flow back in the pipe. For this purpose, the inner surface of the pipe is provided with a porous structure.

During the operation of the pulsating heat pipe (PHP), also referred to as an oscillating heat pipe, the porous structure is not required. The inner surface of the pipe can also be implemented as smooth. In the pulsating heat pipe, too, the heat is transferred by way of a fluid, with parts of the fluid being present in the pipe in gaseous form. Owing to the heat input, the fluid begins to move back and forth in the pipe. This pulsating action gives the heat pipe its name.

The flow of fluid back to the heat source at which the cooling effect is triggered due to the vaporization is effected as a result of alternating boiling and condensation processes, assisted by the geometry of the pipe which forms the channel. The dimensions, in particular the cross-section of the channel, are chosen such that the effect of gravity is less compared to the surface tension and consequently the fluid can also spread out in the channel against gravity. In other words, the geometry is embodied in such a way that the effect of the surface tension dominates relative to gravity. Consequently, a porous structure is no longer necessary for the pulsating heat pipe, but instead the capillary effect comes into play on account of the geometry.

The object underlying the invention is to improve a heat pipe heat sink in particular with regard to cooling performance and manufacturability.

This object is achieved by means of a heat pipe heat sink, the heat pipe heat sink being configured for operation as a pulsating heat pipe, the heat pipe heat sink comprising a body, the body containing internally at least one closed channel, more particularly a channel embodied as alternatingly curved or serpentine, the body comprising a first body portion which is embodied as curved, alternatingly curved, serpentine or U-shaped, a coolant, more particularly a gaseous coolant, being able to flow through the first body portion along the surface of the first body portion, portions of the channel and/or, if there is more than one channel, different channels being arranged parallel to one another. This object is further achieved by means of a power semiconductor unit comprising a heat pipe heat sink of said type and at least one power semiconductor module, the power semiconductor module being connected to the heat pipe heat sink in a thermally conductive manner in such a way that the heat generated due to power loss of the power semiconductor module can be dissipated by means of the heat pipe heat sink to the coolant, more particularly to the gaseous coolant, or to the ambient air. The object is further achieved by means of a power converter comprising a heat pipe heat sink of said type or a power semiconductor unit of said type. The object is further achieved by means of a method for producing a heat pipe heat sink of said type, wherein, in a first step, the body or block parts are produced in a block mold, the body containing a channel or the block parts being connected in such a way that a channel is created in the interior of the connected block parts, the channel extending in a plane, wherein, in a second step, the body or the block parts are formed or bent in such a way that the first body portion is produced having a structure that is curved, alternatingly curved, more particularly curved transversely to the flow direction or a preferred direction of the flow direction of the channel, serpentine or U-shaped.

Further advantageous embodiments of the invention are disclosed in the dependent claims.

The invention is based among other things on the realization that the thermal efficiency of the first body portion in a heat pipe heat sink is very heavily dependent on the thermal conductivity of the material used. By integrating a pulsating heat pipe into the first body portion it is possible to increase the thermal conductivity by a multiple and thus significantly improve thermal efficiency. In particular having better cooling performance means that more expensive materials such as copper can be dispensed with. Generally, however, all materials that are structurally sufficiently stable (and formable) are conceivable, thus e.g. also electrically insulating or extremely corrosion- or wear-resistant materials. Preferably, the body is an aluminum body or a body made of plastic. These are available on the market, can be produced cost-effectively and possess sufficiently good thermal conductivity.

One challenge when it comes to the integration of the pulsating heat pipe into the first body portion is cost-efficient manufacture in order to allow its use in typical industrial applications at normal market prices.

The proposed approach is to produce the individual bodies comprising the first body portion of the heat pipe heat sink from just one component. This is provided with one or more PHP structures and alternately bent for example at greater bending angles (around 180°) such that a kind of serpentine, meandering or U shape is created, wherein here the resulting distances between the bends can be varied as required and at the same time the size of the heat pipe heat sink can also be varied. Alternatively, the bends can be made at predefined distances, for example alternately at greater bending angles, twice by 90° to the right and twice by 90° to the left, in order to achieve a similar result in which the contact area with the heat source can be better varied.

Ideally, the largest part, the body, of the heat pipe heat sink is produced in the level state (e.g. by a stamping, milling or rolling process) or already in an extrusion process. A subsequent reshaping of the body in its first body portion then leads to the final heat sink geometry.

To terminate/connect the PHP structure, end pieces can then be produced, depending on the process. This can happen by means of strip welding, for example.

The connections that extend within the end pieces or within one end piece composed of multiple block-shaped pieces serve for example for connecting multiple channels in series or in parallel to facilitate simultaneous filling. In other words, two or more channels, more particularly two or more adjacent channels, can be connected to one another by means of the end pieces.

The end pieces can be for example stamped, milled, bored, 3D-printed, injection-molded and cast, in particular also by means of lost form. Both additively attached end pieces are possible, as also is the integration of the end piece into the body. In the case of additively attached end pieces, the material can also be other than aluminum. In this case, 3D-printed end pieces or end pieces cast using lost form possess a potential for increasing the performance of the pulsating heat pipe in terms of hydraulic optimization.

It is also possible to seal the ends, in particular both ends, of the body using just one end piece and in particular to connect them simultaneously in order to achieve a circumferential PHP geometry. Depending on geometry, this can lend itself as useful for facilitating a more stable operation of the heat pipe heat sink and/or an easier startup of the pulsating heat pipe. A particular advantage of this arrangement is that only a maximum of two terminating parts, in particular precisely one terminating part, is necessary for the body in order to connect the channel portions. Alternatively, the body can also be implemented without terminating parts. As the channel serves for cooling, it is also referred to in the following as a cooling channel.

Thus, a high level of performance and an easy manufacturability of the heat pipe heat sink can be achieved by virtue of the fact that the body is produced first in a block shape with internal serpentine cooling channels. By a block shape is to be understood a polygonal body which can be formed or bent into a serpentine shape. An example of such a block shape is a cuboid. Such a block shape or such a cuboid does not necessarily have to have even surfaces as edges in this case. Also, these do not have to be parallel to one another in pairs. This is described below phrased with the words that the block substantially corresponds to a cuboid or is implemented substantially in a cuboid shape since the body does not necessarily have to have even surfaces as edges or pairs of parallel surfaces. In order to produce a better heat transfer to the coolant, for example, the surface can be increased compared to an even shape. This can happen for example by means of a wave shape, in particular at parts of the body that are provided for forming the first body portion. Furthermore, it is also possible to roughen the surface by means of projecting or recessed elements. In a next step, said body is reshaped or bent in such a way that it acquires a serpentine or U-shaped embodiment in the first body portion. In this case the body can be bent for example into 90° or 180° bends. Moreover, it is also possible for example to bend the aluminum body into 270° bends, said bends then advantageously directly adjoining one another and having a different direction. A coolant such as air, for example, can flow through this first body portion embodied in a serpentine or U shape. A high level of cooling performance can be achieved as a result.

In the case of the power semiconductor unit, the heat pipe heat sink and the power semiconductor module can form a unit or part of a unit. For example, the baseplate of the power semiconductor module can be formed by the heat pipe heat sink or a part of the heat pipe heat sink.

It has proved particularly advantageous for the heat transfer in the heat pipe heat sink if the preferred flow direction of the coolant is realized laterally with respect to the surfaces that are intended to be populated by the heat sources.

In an advantageous embodiment of the invention, a cross-section of the body oriented at right angles to the channel in the first body portion has the same dimensions over an uninterrupted length of at least 80% of the overall length of the body along the channel. In other words, in an advantageous embodiment of the invention, the body is embodied as uninterruptedly joint-free over the length in the first direction over at least 80% of the dimension in a first direction, the first direction corresponding to the preferred direction of the course of the channel. A particular advantage of the proposed exemplary embodiment of the heat pipe heat sink is that no or, if at all, only a few terminating parts are required. In this case, as an alternative to the unvarying cross-section, the cross-section of the channel can have the same dimensions. In this case there are substantially no joints present in the first body portion, with the exception for example of one or more terminating parts, with the result that this is embodied partly or even completely free of joints. Dispensing with joints means that the reshaping can be performed particularly easily. The risk of breakage, which is otherwise increased at joints, is not present or only present to a reduced extent thanks to this embodiment.

The major part of the first body portion is free of interruptions with terminating parts. This is expressed in that the first body portion has the same cross-section over at least 80% of its length along the channel. In this case the cross-section of the channel advantageously also remains substantially constant over this length. Changes in the channel structure are produced only as a result of the bending stages in the manufacturing process.

In a further advantageous embodiment of the invention, the heat pipe heat sink has cooling fins on the first body portion. By mounting cooling fins onto the surface of the body, in particular in the region of the first body portion, it is possible to dissipate the heat transferred from the heat pipe heat sink to the coolant flowing along the first body portion even better and more effectively. In particular in the case of small temperature differences between the heat pipe heat sink and the coolant, such as air, for example, the heat transfer can be significantly improved.

In a further advantageous embodiment of the invention, the heat pipe heat sink comprises at least two bodies. It has proved advantageous to construct the heat pipe heat sink on a modular basis with a plurality of bodies, i.e. at least two bodies. In this case the bodies can be implemented in an identical design or they can be different. This results in a redundant cooling configuration. Even if there is a failure in the cooling effect of one body, due for example to a defect in leakage tightness in the channel, a sufficient cooling effect continues to be ensured by the remaining bodies. It is also possible to produce heat pipe heat sinks having different levels of performance based on the use of a different number of identical bodies for forming the heat pipe heat sink. In other words, the heat pipe heat sink comprises a plurality of identical bodies. In this case the number of bodies is yielded as a function of the performance of the heat pipe heat sink. This enables a plurality of heat pipe heat sinks having different levels of performance to be produced at reasonable cost.

In a further advantageous embodiment of the invention, the bodies are arranged in series when seen from the perspective of the coolant flowing therethrough. With this arrangement, the bodies can be easily secured to one another since they are made of the same material (aluminum) and consequently are subject to the same expansion when heated. Signs of fatigue due to differences in expansion are thus reliably avoided and the heat pipe heat sink achieves a long service life.

In a further advantageous embodiment of the invention, the heat pipe heat sink comprises a baseplate, the baseplate being connected to the body in a heat-conducting manner, the baseplate being provided for connecting to a heat source. In this case the baseplate can be designed in such a way that the heat source, for example a semiconductor, also referred to as a power semiconductor at higher power levels and power losses associated therewith, can be securely attached to the baseplate of the heat pipe heat sink. At the same time, a heat spreading effect is produced by the baseplate such that the heat is evenly transferred to the body. In this case the baseplate can have recesses which can accommodate a part of the serpentine or U-shaped body section of the first portion of the body. By increasing the size of the contact area between body and baseplate, the heat transfer between baseplate and body is improved and the performance of the heat pipe heat sink increases. The baseplate and the body can be permanently joined to one another for example by means of soldering, welding, adhesive bonding, clamping, pressing or some other method.

In a further advantageous embodiment of the invention, the heat source is disposed at the edge of the baseplate. This arrangement is particularly advantageous because it allows a particularly good heat transfer to be achieved from the heat source via the baseplate to the cooling channel. As a result, the heat pipe heat sink is particularly efficient with regard to the transfer of heat to the environment.

In a further advantageous embodiment of the invention, the first body portion is embodied in a U shape, the first body portion being connected to a terminating part, in particular to itself, in such a way that a ring-shaped body is produced. A plurality of independent cooling channels can be produced in a heat pipe heat sink by means of this embodiment.

The plurality of cooling channels can in this case be implemented for example by means of a series or parallel connection of several or all of the cooling channels.

Thus, a heat pipe heat sink constructed in this manner possesses a high level of redundancy. Furthermore, cooling air can easily flow through the ring-shaped bodies of the heat pipe heat sink. Also, the first part of the body can easily be produced by means of just one bending process.

What is to be understood by the ring shape is a closed shape. This includes for example a circular shape, an oval shape or also two parallel cut sections which are closed at their ends by means of semicircular portions.

In a further advantageous embodiment of the invention, the body comprises a second body portion that has a plane surface, the surface being provided for creating the connection to a heat source. In this embodiment, the heat source is arranged particularly close to the channel of the body. Thanks to the proximity to this channel, the highly efficient cooling action of the heat pipe can be particularly effectively exploited. In particular, it is advantageous to arrange the heat source in the vicinity of a number of cooling channels or a number of subsections of the cooling channel or cooling channels. It has proven advantageous in this case to arrange the heat source preferably flat on a plane that is parallel to the area in which the cooling channels run. High quantities of heat can be conveyed away from the heat source with no appreciable time delay. Moreover, the heat pipe heat sink can be constructed from just a few parts. In the simplest case, the heat pipe heat sink consists merely of the body with a first portion to allow the cooling air to flow through and a second portion for the arrangement of the heat source. This enables a highly efficient and lightweight heat sink to be produced in a simple and cost-effective manner.

Furthermore, flows within the channel with preferred direction are also possible with annularly closed first body portions. In this case the use of a sleeve-like connecting piece, among other things, may also prove suitable. This sleeve is characterized by a circumferential collar which ensures the precise positioning of the two open ends of the U-shaped portion of the body so that the latter is both precisely positioned and mechanically secured against displacement. The connecting sleeve preferably contains the filling and sealing mechanism.

In a further advantageous embodiment of the invention, the body is assembled from at least two block parts. The channel can be easily produced if the body is composed of two block parts. Parts of the channel can then be arranged in each case at a boundary area of the block parts. The body can subsequently be formed from the block parts for example by soldering, welding, adhesive bonding, clamping, pressing or some other method. The cooling channel can be incorporated particularly easily into the body in this way.

In this case, during the production of the body from two block parts, the two block parts can first be connected to the body or alternatively the block parts can first be reshaped or bent and then connected to form a body.

In a further advantageous embodiment of the invention, the body is produced in block form by means of a continuous casting process. Generally speaking, in this further advantageous embodiment of the invention, the body or the block parts are produced in a block mold by means of an extrusion process, in particular an extrusion press process or a continuous casting process, or an injection molding process. The continuous casting process or alternatively the extrusion process has proved its worth as a cost-effective method for manufacturing bodies. One approach in this case is the at least partial fabrication of the body and the associated internal structure of the pulsating heat pipe by means of extrusion pressing. However, if only individual U-shaped first body portions of the body are provided, these must then in turn all have connecting structures at both ends in order to terminate the internal cooling structure of the oscillating heat pipe, which can in turn lead to increased costs. Best suited in this case is aluminum, which currently also offers the best cost-benefit ratio generally for heat sinks. For certain applications, however, the use of plastic is also conceivable here as an alternative. In particular if the cooling structure is exposed to humidity or corrosive media or if an electrical insulation is required, the use of plastic is advantageous.

In a further advantageous embodiment of the invention, the body is milled, forced or pressed, in particular the channel is milled, forced or pressed into the two block parts. Milling is also a simple manufacturing method. Particularly for the production of the body from two block parts, milling lends itself as a suitable method of incorporating the channel into the two block parts. The individual block parts can be produced as an identical block in a first step. The structure of the channel is milled, forced or pressed into the block parts in a second step. In this case the milling of the channel sections and consequently the forming of the channel can be designed differently for example depending on the embodiment of the heat source.

Furthermore, when connected block parts are used, channel connectors and filling openings can be integrated and as a result it may be possible to dispense with further connecting or sealing elements.

In a further advantageous embodiment of the invention, the cross-section of the channel has a minimum dimension in the range of 0.5 mm to 5 mm. This geometry has proved particularly favorable in this case for producing the capillary effect for a plurality of fluids. At the same time, with these dimensions a sufficient fluid flow with little pressure loss is ensured and consequently a particularly good cooling effect achieved. If water is used, possibly with an admixture of antifreeze, a minimum expansion in the range of 4 mm to 5 mm is advantageous since a sufficient capillary effect is already achievable by this means. Other fluids require smaller dimensions of up to 0.5 mm at least in part in order to realize an adequate capillary effect.

It has been shown that a particularly high power density and heat transport performance can be achieved with the geometry that has these dimensions. One reason among others for this is that the material is transported almost exclusively via the vapor pressure present in the channel. The heat transfer is particularly rapid as a result. This enables a high quantity of heat to be transferred and consequently a high power density of a corresponding heat sink to be ensured.

The invention is described and explained in more detail below with reference to the exemplary embodiments illustrated in the figures, in which:

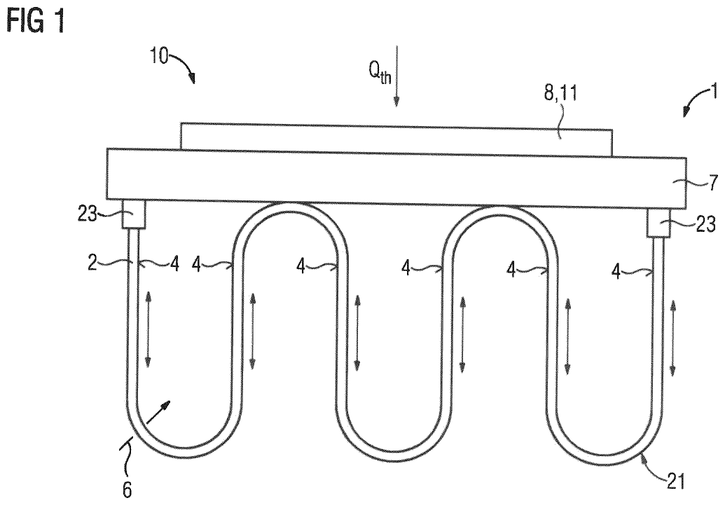

FIG. 1 to FIG. 4 show exemplary embodiments of heat pipe heat sinks and power semiconductor units,

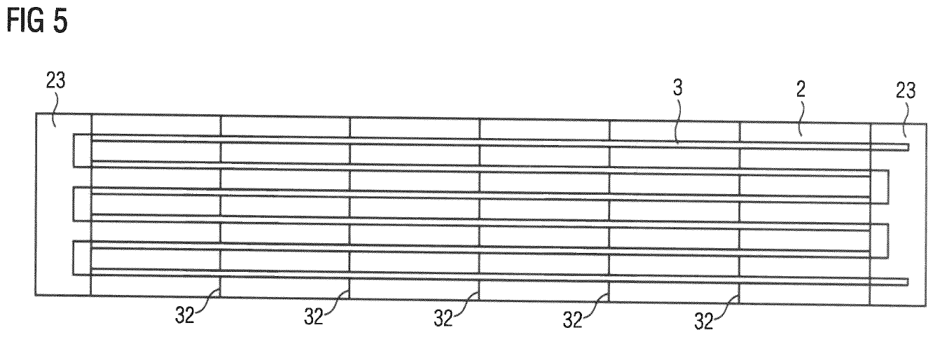

FIG. 5 to FIG. 7 show exemplary embodiments of a body,

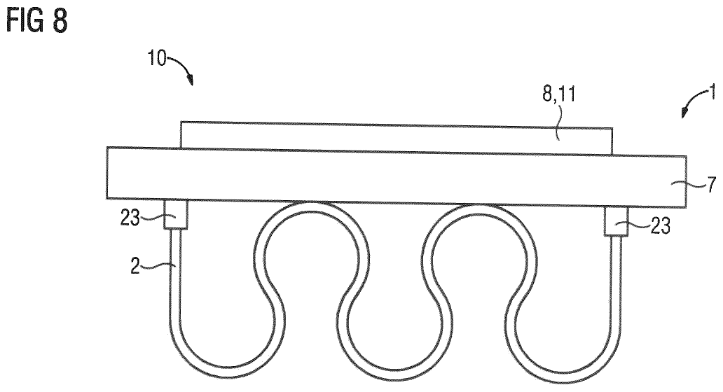

FIG. 8 to FIG. 14 show exemplary embodiments of heat pipe heat sinks, and

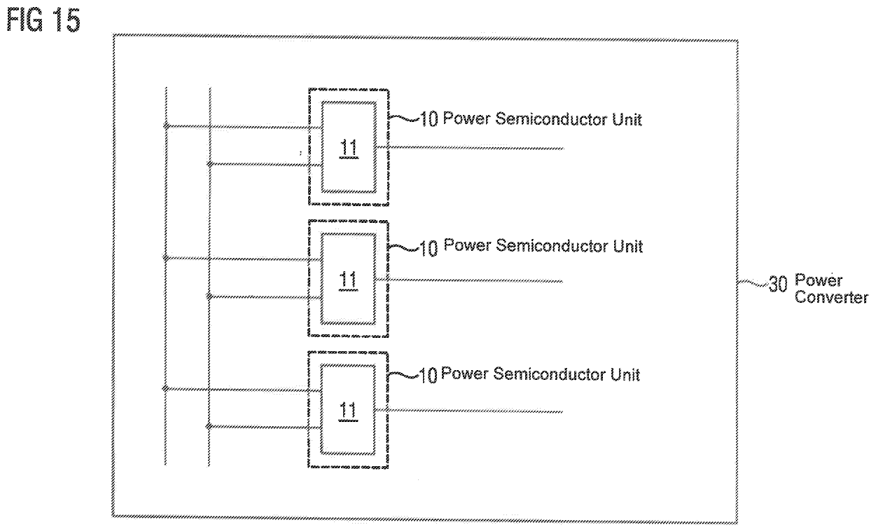

FIG. 15 shows a power converter.

FIG. 1 shows a heat pipe heat sink 1 which comprises a body 2 and a baseplate 7. Arranged on the baseplate 7 is a heat source 8 which introduces a quantity of heat Qₜₕ into the heat pipe heat sink 1. If the heat source 8 is a power semiconductor module 11, the combination of heat pipe heat sink 1 and power semiconductor module 11 is referred to as a power semiconductor unit 10. The body 2 has a first body portion 21 formed into a substantially serpentine shape. A coolant 6, more particularly a gaseous coolant 6 such as air, for example, flows along the surface 4 of the first body portion 21. This coolant 6 is represented with the aid of an arrow in the present figure. The body 2 is terminated with a terminating part 23. The terminating part 23 can advantageously also be used for filling a channel 3 (not shown in further detail here).

The pulsating fluid-gas mixture in the interior of the channel 3 of the heat pipe heat sink 1 is indicated by the vertical arrows having the two arrow tips.

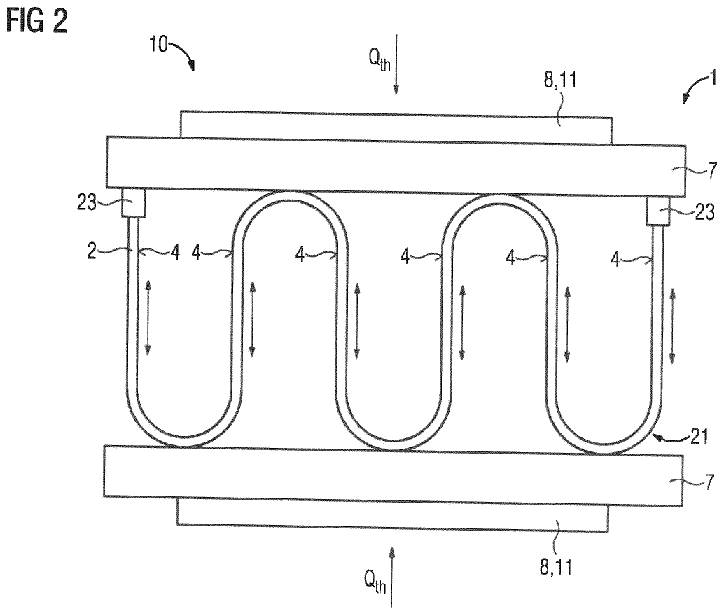

FIG. 2 shows a further exemplary embodiment of a heat pipe heat sink 1 or of a power semiconductor unit 10. This heat pipe heat sink 1 has two baseplates 7, on each of which is arranged a heat source 8 or a power semiconductor module 11 which inputs a quantity of heat Qₜₕ into the heat pipe heat sink 1. To avoid repetition, reference is made to the description relating to FIG. 1, as well as to the reference signs introduced there. Here, too, the coolant 6 flows through the heat pipe heat sink 1 along the surface 4 of the first body portion 21 of the body 2, though this is not shown in further detail by means of the arrow and the associated reference sign in this and the following figures.

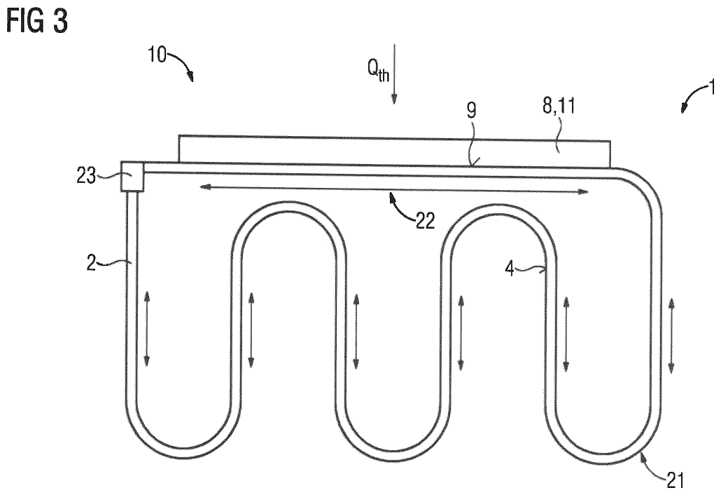

FIG. 3 shows a further exemplary embodiment of a heat pipe heat sink 1. This heat pipe heat sink 1 has no baseplate 7. The heat pipe heat sink 1 is therefore implemented without a baseplate. As well as the first body portion 21 embodied in a serpentine shape, the body has a second body portion 22 with a level surface 9. The heat source 8 or the power semiconductor module 11 is arranged on the level surface 9 of the second body portion 22. To avoid repetition, reference is made to the description relating to FIG. 1 and FIG. 2, as well as to the reference signs introduced there.

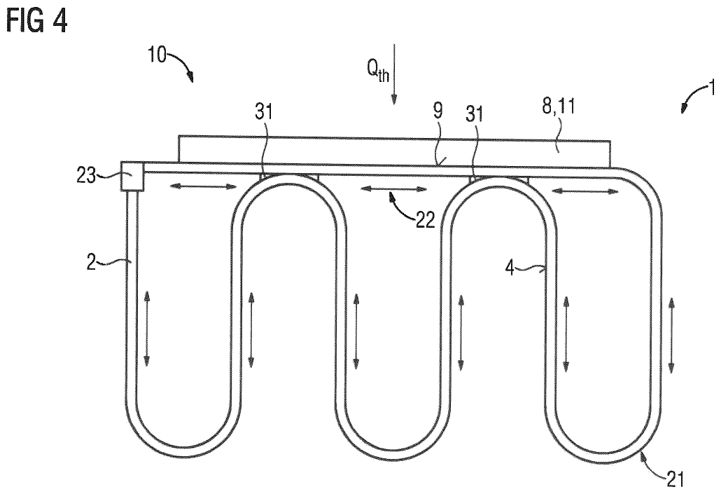

FIG. 4 shows a further exemplary embodiment of a heat pipe heat sink 1. This heat pipe heat sink 1 has connections 31 between the first body portion 21 and the second body portion 22. By means of these connections 31, the quantity of heat Qₜₕ from the heat source 8 that is input into the second body portion 22 of the body 2 is transferred even more efficiently to the first body portion 21 of the body 2 in which the transition to the coolant or the gaseous coolant takes place. To avoid repetition, reference is made to the description relating to FIGS. 1 to 3, as well as to the reference signs introduced there.

FIG. 5 shows an exemplary embodiment of a body 2. This body 2 is embodied in a block shape. A channel 3 is situated within the body 2. Contained in this channel 3 is a fluid in two phases by means of which the mode of operation of the heat pipe, in particular of the pulsating heat pipe, is realized. Terminating parts 23 of the body 2 serve for terminating and where applicable for filling the channel. In the course of the production of the heat pipe heat sink 1, the body 2 is formed at the bending positions 32 into a serpentine or U shape. The section of the body 2 which is embodied as serpentine or U-shaped then forms the first body portion 21 which serves to transfer the heat to the coolant 6. To avoid repetition, reference is made to the description relating to FIGS. 1 to 4, as well as to the reference signs introduced there.

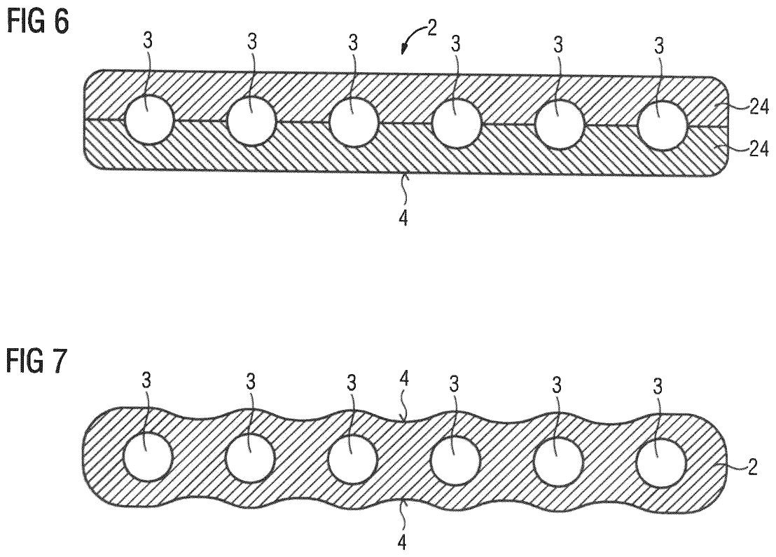

FIG. 6 shows the body 2 of FIG. 5 in a different sectional view. Furthermore, the body 2 is divided into two block parts 24 which are joined to one another during the production process to form the body 2. To avoid repetition, reference is made to the description relating to FIGS. 1 to 5, as well as to the reference signs introduced there. Internally, the body 2 contains the channel 3. The substantially rectangular cross-section is produced from the block-shaped embodiment of the body 2. However, in order to increase the surface 4 of the first body portion 21 and thereby improve the heat transfer from the heat pipe heat sink to the coolant 6, the body can have at its surface, in particular at the surface 4 of the first body portion 21, a wavelike structure, as shown in FIG. 7. Alternatively, a sawtooth or triangular shape is also possible. These shapes also improve the heat transfer from the heat pipe heat sink 1 to the coolant 6 and hence the performance of the heat pipe heat sink. To avoid repetition, reference is made to the description relating to FIGS. 1 to 6, as well as to the reference signs introduced there.

FIG. 8 shows a further exemplary embodiment of a heat pipe heat sink 1 or of a power semiconductor unit 10. To avoid repetition, reference is made to the description relating to FIGS. 1 to 7, as well as to the reference signs introduced there. In this case the serpentine part has bends which go beyond an angle of 180°. For example, these can have a range of 270°, opposite bends directly adjoining one another and having no or at least not necessarily a straight section. This enables the effective surface 4 of the first body portion 21 for the transfer of heat from the heat pipe heat sink 1 to the coolant 6 to be increased further. This further improves the performance of the heat pipe heat sink 1.

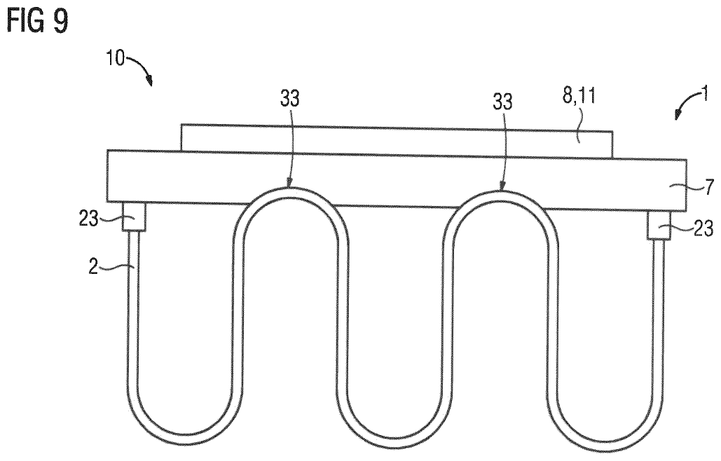

FIG. 9 shows a further exemplary embodiment of a heat pipe heat sink 1 or of a power semiconductor unit 10. To avoid repetition, reference is made to the description relating to FIGS. 1 to 8, as well as to the reference signs introduced there. The baseplate 7 of this exemplary embodiment has recesses 33. These recesses 33 are embodied in such a way as to accommodate a part of the first body portion 21 of the body 2. It has proved advantageous in this case to implement the recesses 33 with a bent boundary layer relative to the baseplate 7. This enables the body 2 to butt against the baseplate 7. As a result of the recess 33, the effective surface for the transfer of heat between baseplate 7 and body 2 is increased in size. This increase in the size of the effective surface leads to an improved performance of the heat pipe heat sink 1.

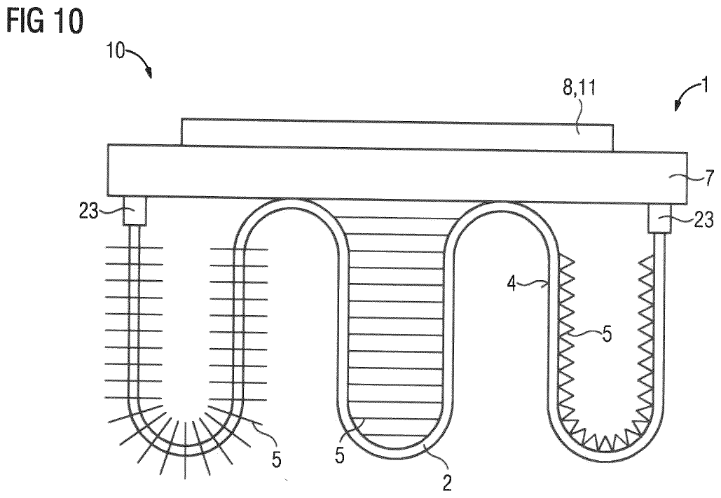

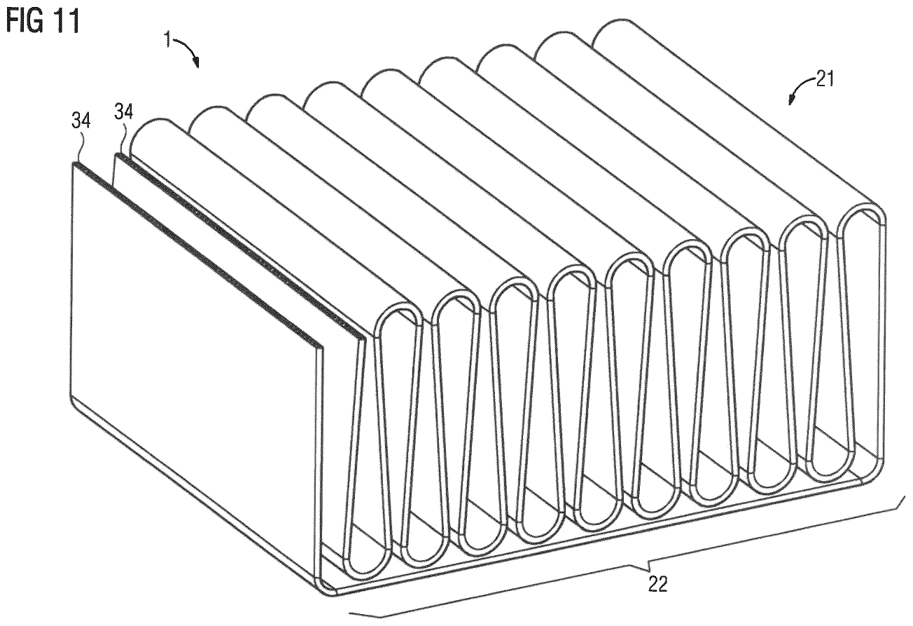

FIG. 10 shows a further exemplary embodiment of a heat pipe heat sink 1 or of a power semiconductor unit 10. To avoid repetition, reference is made to the description relating to FIGS. 1 to 9, as well as to the reference signs introduced there. In this case cooling fins 5 are arranged on the body 2 in the first body portion 21. These are often referred to as ribs or pins. They can be arranged as rods or plates on the surface 4 of the first body portion 21. Alternatively or in addition, they can also be arranged in a triangular shape, such as a prism-shaped structure on the surface 4 of the first body portion 21, for example. It is also possible, as shown in the center, to arrange the cooling fins between two sections of the first body portion 21.

It has proven particularly advantageous if the cooling fins 5 extend parallel to the baseplate 7 or parallel to the second body portion 21. In that case the heat buildup in the cooling fins 5 is particularly homogeneous and no mechanical stresses are produced due to inhomogeneous heating of parts of the heat pipe heat sink 1.

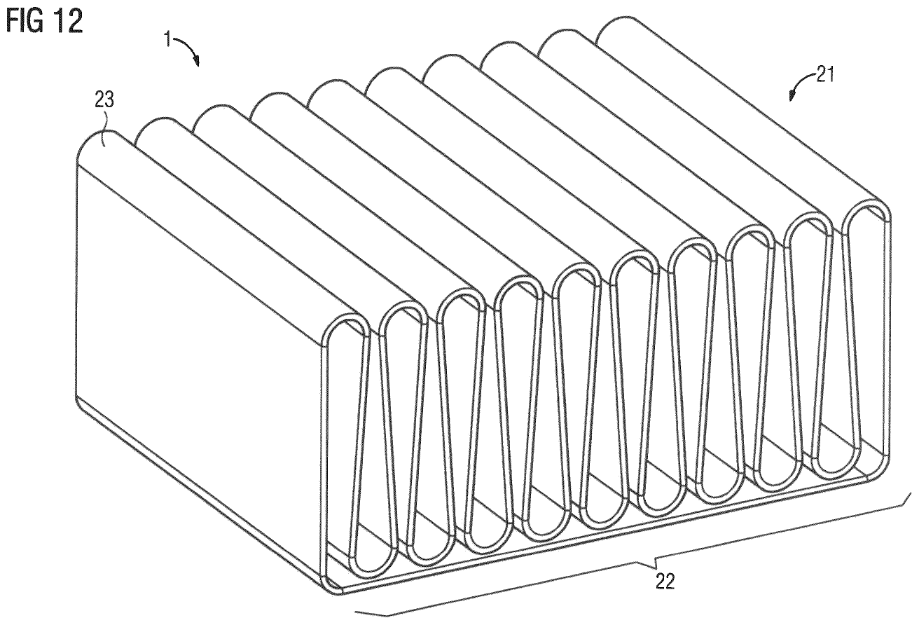

FIG. 11 shows a further exemplary embodiment of a heat pipe heat sink 1 which is implemented without a baseplate 7. To avoid repetition, reference is made to the description relating to FIGS. 1 to 10, as well as to the reference signs introduced there. The heat source 8 can be arranged on the second body portion. In this case the heat pipe heat sink has two open ends 34. If these open ends 34 are closed with the aid of a terminating part 23, the body 2 acquires a closed shape. This is illustrated in FIG. 12. To avoid repetition, reference is made to the description relating to FIGS. 1 to 11, as well as to the reference signs introduced there.

The surface shown hidden at the bottom in FIG. 12 is suitable for engaging in contact with the heat source on account of its immediate proximity to a number of channels or channel segments.

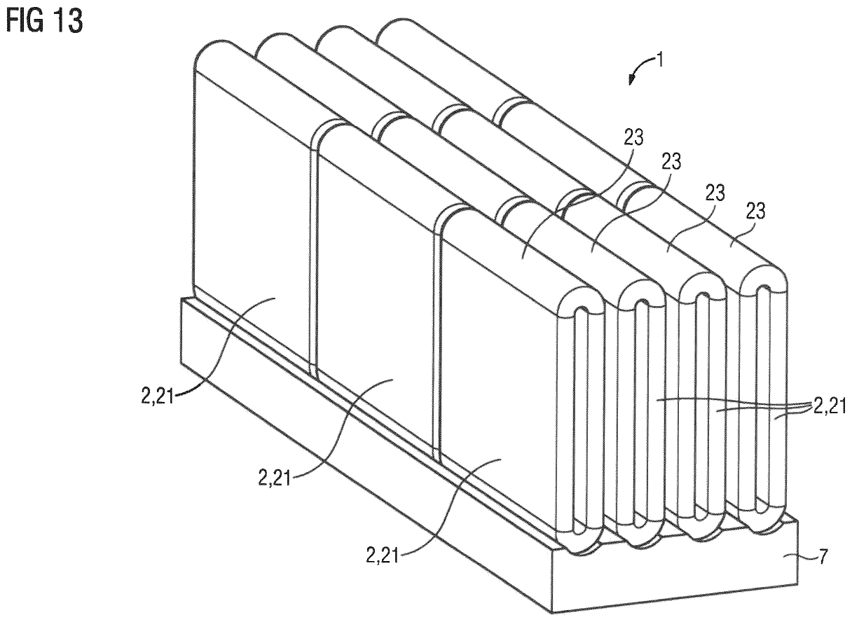

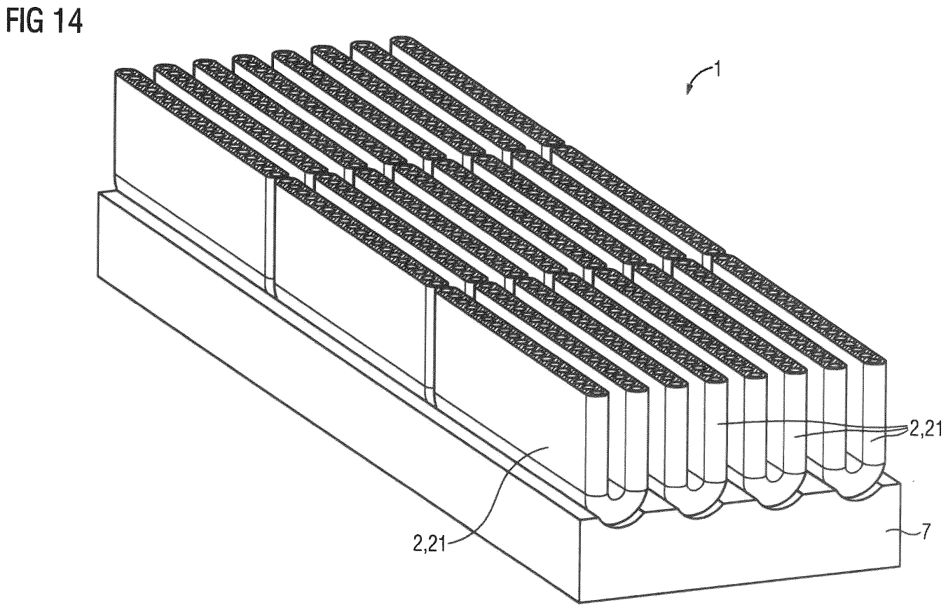

FIG. 13 shows a further exemplary embodiment of a heat pipe heat sink 1. To avoid repetition, reference is made to the description relating to FIGS. 1 to 12, as well as to the reference signs introduced there. This heat pipe heat sink 1 comprises a plurality of bodies 2. These are embodied as U-shaped in this exemplary embodiment. The use of a terminating part 23 results in a circular shape through which the coolant 6, more particularly the gaseous coolant 6, can flow. The bodies are connected to the baseplate 7, which among other things ensures the bodies are properly aligned relative to one another. Alternatively, the first body section may also be embodied in a serpentine shape. As a result, the use of a plurality of serpentine-shaped first portions 21 of the body 2 is also possible when a plurality of bodies 2 are used for forming a heat pipe heat sink 1. An arrangement without terminating parts 23 is shown in FIG. 14, from which the U-shaped embodiment of the bodies 2 can be seen.

FIG. 15 shows a power converter 30 comprising three power semiconductor units 10. Each of the power semiconductor units 10 has at least one power semiconductor module 11. The power semiconductor module is cooled or gives off heat by means of a heat pipe heat sink 1 (not shown in further detail here). In this case the heat pipe heat sink 1 can be embodied according to one of the previously explained figures.

To sum up, the invention relates to a heat pipe heat sink, wherein the heat pipe heat sink is configured for operation as a pulsating heat pipe, wherein the heat pipe heat sink has a body. In order to improve the performance and manufacturability of the heat pipe heat sink, it is proposed that internally the body contains at least one closed channel, more particularly a serpentine channel, wherein the body comprises a first body portion which is embodied as serpentine or U-shaped, wherein a coolant, more particularly a gaseous coolant, can flow through the first body portion along the surface of the first body portion. The invention further relates to a method for producing a heat pipe heat sink of said type, wherein in a first step the body or block parts are produced in a block shape, wherein the channel extends in a plane, wherein in a second step the body or the block parts are formed or bent in such a way that the first body portion is produced with a serpentine or U-shaped structure. The invention further relates to a power semiconductor unit and to a power converter comprising a heat pipe heat sink of said type, wherein the heat generated can be transferred to the coolant by means of the heat pipe heat sink.

In other words, the invention relates in summary to a heat pipe heat sink, wherein the heat pipe heat sink is configured for operation as a pulsating heat pipe, wherein the heat pipe heat sink comprises a body. In order to improve the performance and manufacturability of the heat pipe heat sink, it is proposed that internally the body contains at least one closed channel, more particularly an alternatingly curved or serpentine channel, wherein the body comprises a first body portion which is embodied as curved, alternatingly curved, serpentine or U-shaped, wherein a coolant, more particularly a gaseous coolant, can flow through the first body portion along the surface of the first body portion, wherein portions of the channel and/or, if there is more than one channel, different channels are arranged parallel to one another. The invention further relates to a method for producing a heat pipe heat sink of said type, wherein in a first step the body or block parts are produced in a block shape, wherein the channel extends in a plane, wherein in a second step the body or the block parts are formed or bent in such a way that the first body portion is produced with an alternatingly curved, serpentine or U-shaped structure. The invention further relates to a power semiconductor unit and to a power converter comprising a heat pipe heat sink of said type, wherein the heat generated can be transferred to the coolant by means of the heat pipe heat sink.

What is claimed is:

1.-20. (canceled)

21. A heat pipe heat sink operating as a pulsating heat pipe, the heat pipe heat sink comprising:
a body comprising internally a closed channel which has in particular an alternatingly curved or serpentine configuration and in which a fluid is arranged such that part of the fluid is present in gaseous form, said channel having a periphery which is designed to be smooth, said body comprising a first body portion which is embodied as curved, alternatingly curved, serpentine or U-shaped; and
a coolant, in particular a gaseous coolant, flowing through the first body portion along a surface of the first body portion,
wherein portions of the channel are arranged parallel to one another and/or in the presence of more than one channel, different channels are arranged parallel to one another, and
wherein the body is composed of two block parts, with parts of the channel being arranged on a boundary area of the two block parts, respectively.

22. The heat pipe heat sink of claim 21, wherein the body has a cross-section which is oriented at a right angle to the channel in the first body portion and has a same dimension over an uninterrupted length of at least 80% of an overall length of the body along the channel.

23. The heat pipe heat sink of claim 21, further comprising cooling fins arranged on the first body portion.

24. The heat pipe heat sink of claim 21, further comprising at least one further said body.

25. The heat pipe heat sink of claim 24, wherein the body and the at least one further said body are arranged in series when seen from a perspective of the coolant flowing therethrough.

26. The heat pipe heat sink of claim 21, further comprising:
a heat source; and
a baseplate connected to the body in a thermally conductive manner and designed for connecting to the heat source.

27. The heat pipe heat sink of claim 26, wherein the heat source is arranged at an edge of the baseplate.

28. The heat pipe heat sink of claim 21, wherein the first body portion has a U-shaped configuration, the first body portion being connected to a terminating part, in particular to itself such as to define a ring-shaped body.

29. The heat pipe heat sink of claim 21, further comprising a heat source, said body comprising a second body portion which has a level surface for connection to the heat source.

30. The heat pipe heat sink of claim 21, wherein the channel has a cross-section with a minimum dimension in a range of 0.5 mm to 5 mm.

31. The heat pipe heat sink of claim 21, wherein the first body portion is embodied without joints.

32. The heat pipe heat sink of claim 21, wherein the body is embodied monolithically.

33. A power semiconductor unit, comprising:
a heat pipe heat sink comprising a body comprising internally a closed channel which has in particular an alternatingly curved or serpentine configuration and in which a fluid is arranged such that part of the fluid is present in gaseous form, said channel having a periphery which is designed to be smooth, said body comprising a first body portion which is embodied as curved, alternatingly curved, serpentine or U-shaped, and a coolant, in particular a gaseous coolant, flowing through the first body portion along a surface of the first body portion, wherein portions of the channel are arranged parallel to one another and/or in the presence of more than one channel, different channels are arranged parallel to one another, and wherein the body is composed of two block parts, with parts of the channel being arranged on a boundary area of the two block parts, respectively; and
a power semiconductor module connected to the heat pipe heat sink in a thermally conductive manner in such way that heat generated due to power loss of the power semiconductor module is capable of being dissipated via the heat pipe heat sink to the coolant or to ambient air.

34. A power converter, comprising:
a heat pipe heat sink comprising a body comprising internally a closed channel which has in particular an alternatingly curved or serpentine configuration and in which a fluid is arranged such that part of the fluid is present in gaseous form, said channel having a periphery which is designed to be smooth, said body comprising a first body portion which is embodied as curved, alternatingly curved, serpentine or U-shaped, and a coolant, in particular a gaseous coolant, flowing through the first body portion along a surface of the first body portion, wherein portions of the channel are arranged parallel to one another and/or in the presence of more than one channel, different channels are arranged parallel to one another, and wherein the body is composed of two block parts, with parts of the channel being arranged on a boundary area of the two block parts, respectively; or
a power semiconductor unit as set forth in claim 33.

35. A method for producing a heat pipe heat sink, comprising:
producing block parts in block form;
connecting the block parts to a body such as to form a channel in an interior of the connected block parts, with the channel extending in a plane; and
forming or bending the body or the block parts in such a way as to produce a first body portion with a structure that is curved, alternatingly curved, in particular curved transversely with respect to a flow direction or a preferred direction of a flow direction of the channel, serpentine or U-shaped.

36. The method of claim 35, wherein the body is embodied as uninterruptedly free of joints over a length in a first direction over at least 80% of a dimension in a first direction, with the first direction corresponding to a preferred direction of a course of the channel.

37. The method of claim 35, wherein the body is formed by reshaping from precisely one part in block form.

38. The method of claim 35, wherein the body is formed from at least two block parts.

39. The method of claim 35, wherein the body or the block parts is or are produced in a block mold using an extrusion method, in particular an extrusion press method or a continuous casting method, or an injection molding method.

40. The method of claim 35, wherein the body is milled, forced or pressed, in particular the channel is milled, forced or pressed into the block parts.
